(19) United States
(12) Patent Application Publication
(10) Pub. No.: US 2026/0239594 A1
(43) Pub. Date: Aug. 13, 2026

(54) SEMICONDUCTOR DEVICE AND MANUFACTURING METHOD THEREOF

(71) Applicant: TAIWAN SEMICONDUCTOR MANUFACTURING COMPANY LTD., HSINCHU (TW)

(72) Inventors: WAI-KIT LEE, TUEN MUN (HK); KATHERINE H. CHIANG, NEW TAIPEI CITY (TW)

(21) Appl. No.: 19/051,226

(22) Filed: Feb. 12, 2025

(51) Int. Cl. H10B 12/00

(52) U.S. Cl. CPC H10B 12/00

(57) ABSTRACT

A semiconductor device and a method for forming the semiconductor device are disclosed. The semiconductor device includes a substrate; a first transistor, and a second transistor. The first transistor includes a first gate electrode on the substrate and a first channel layer on the first gate electrode and extending along a first direction. The second transistor is stacked over the first transistor along a second direction substantially orthogonal to the first direction. The second transistor includes a second gate electrode and a second channel layer on the second gate electrode.

### BACKGROUND

With the advancement of semiconductor technology, the size of semiconductor devices (e.g., memory devices) is continually shrinking. This reduction in size helps to decrease the occupied area of the devices, thereby increasing their density. Therefore, one of the current development goals in semiconductor technology is to explore ways to further reduce the occupied area of semiconductor devices so as to increase the density thereof.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is an exemplary circuit diagram of a semiconductor device according to aspects of the present disclosure in one or more embodiments.

FIGS. 2A, 3A, 4A, 5A, 6A, 7A, 8A, 9A, 10A, 11A, 12A, 13A, and 14A illustrate top views of various stages of manufacturing a semiconductor device, in accordance with some embodiments of the present disclosure.

FIGS. 2B, 3B, 4B, 5B, 6B, 7B, 8B, 9B, 10B, 11B, 12B, 13B and 14B are cross-sectional views along line A-A′ of FIGS. 2A, 3A, 4A, 5A, 6A, 7A, 8A, 9A, 10A, 11A, 12A, 13A, and 14A, respectively.

FIGS. 2C, 3C, 4C, 5C, 6C, 7C, 8C, 9C, 10C, 11C, 12C, 13C, and 14C are cross-sectional views along line B-B′ of FIGS. 2A, 3A, 4A, 5A, 6A, 7A, 8A, 9A, 10A, 11A, 12A, 13A, and 14A, respectively.

FIG. 15 is a cross-sectional view illustrating a semiconductor device according to aspects of the present disclosure in one or more embodiments.

FIG. 16 is a flowchart of a method for manufacturing a semiconductor device according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “substantial” or “substantially” generally mean within 10%, 5%, 1% or 0.5% of a given value or range. Alternatively, the terms “about,” “substantial” or “substantially” mean within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “about,” “substantial” or “substantially.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

The embodiments of the present disclosure provide a semiconductor device including a 2T0C (two transistors and no capacitor) dynamic random-access memory (DRAM) structure. The semiconductor device includes a first transistor and a second transistor stacked over the first transistor. The first transistor and second transistor are disposed in a back-end-of-line (BEOL) circuit level of the semiconductor device. Further, each of the first transistor and second transistor has a backgate-TFT structure, where the gate and source/drain are disposed on the opposite sides of the channel layer. As a result, the semiconductor device of the present disclosure has a greater stacking density compared to comparative semiconductor devices.

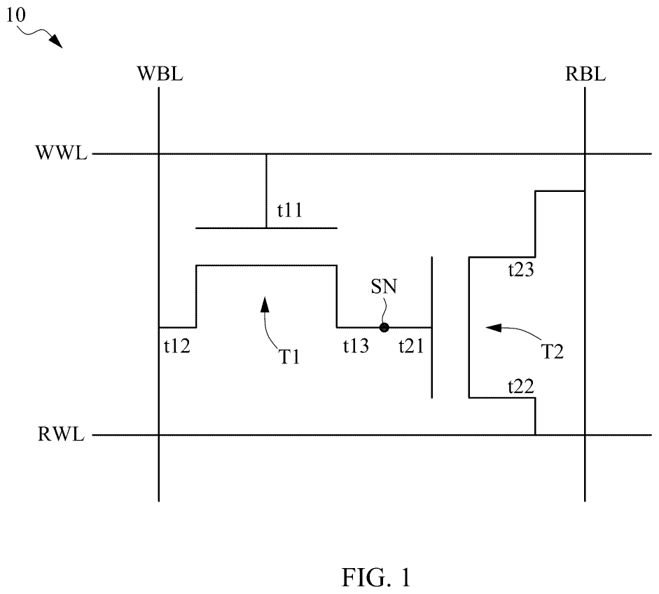

FIG. 1 is an exemplary circuit diagram of a semiconductor device 10 according to aspects of the present disclosure in one or more embodiments.

The semiconductor device 10 includes transistors T1 and T2. In some embodiments, the transistor T1 can be a write transistor, which includes terminals t11, t12, and t13. In some embodiments, the transistor T2 can be a read transistor, which includes terminals t21, t22, and t23. The terminal t11 is a gate terminal of the transistor T1 and is connected to a write word line WWL. The terminal t12 is a drain terminal of the transistor T1 and is connected to a write bit line WBL. The terminal t13 is a source terminal of the transistor T1 and is connected to the first terminal t21 of the transistor T2. The terminal t21 is a gate terminal of the transistor T2. A storage node SN can be defined between the third terminal t13 of the transistor T1 and the first terminal t21 of the transistor T2. The terminal t22 of the transistor T2 is a drain terminal of the transistor T2 and is connected to a read word line RWL. The terminal t23 is a source terminal of the transistor T2 and is connected to a read bit line RBL.

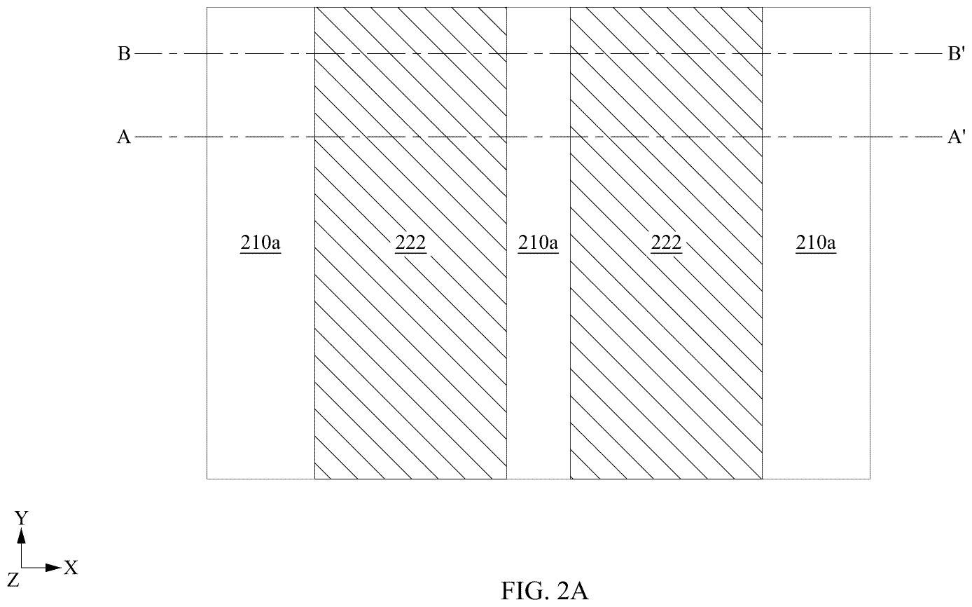

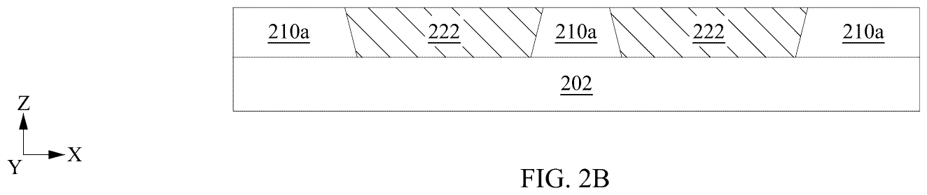

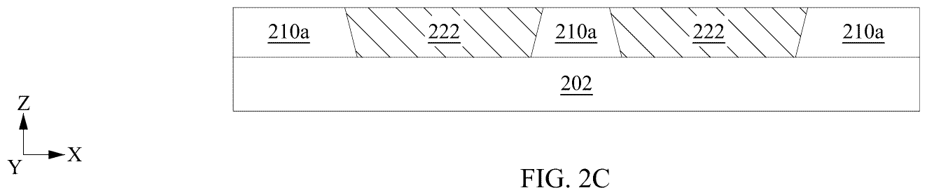

FIGS. 2A to 14A, FIGS. 2B to 14B, and FIGS. 2C to 14C illustrate various stages of manufacturing a semiconductor device 20, in accordance with some embodiments of the present disclosure. FIGS. 2A to 14A are top views. FIGS. 2B to 14B are cross-sectional views along line A-A′, and FIGS. 2C to 14C are cross-sectional views along line B-B′ of FIGS. 2A to 14A, respectively. It should be noted that some features are omitted from top views for brevity.

The semiconductor device 20 can perform the functions of the circuit diagram of the semiconductor device 10 as shown in FIG. 1. In some embodiments, the semiconductor device 20 is a memory device which includes a 2T0C DRAM structure. The cross-sectional views of FIGS. 2B to 14B depict the detailed processes of forming the interconnections between the first source/drain (S/D) electrode of the write transistor and write bit line as well as the interconnections between the first S/D electrode of the read transistor and the read bit line. The cross-sectional views of FIGS. 2C to 14C depict the detailed processes of forming the interconnections between the second S/D electrode of the write transistor and the gate electrode of the read transistor as well as the interconnections between the second S/D electrode of the read transistor and the read word line.

Referring to FIGS. 2A, 2B, and 2C, a carrier 202 is provided. A dielectric layer 210a and conductive features 222 are formed on the carrier 202. In some embodiments, the carrier 202 includes a substrate and multilayer devices and/or elements formed on the substrate. The substrate may be a semiconductor substrate, such as a bulk semiconductor, a semiconductor-on-insulator (SOI) substrate, or the like, which may be doped (e.g., with a p type or an n type dopant) or undoped. The substrate can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. In some embodiments, the substrate may have a multilayer structure, or the substrate may include a multilayer compound semiconductor structure.

In some embodiments, the carrier 202 includes devices and/or elements formed in the front end of the line (FEOL) circuit level of a semiconductor device. The devices and/or elements include, for example, active regions (e.g., oxide-definition (OD) region), transistors, S/D regions, S/D contacts, and/or other devices and/or elements. In this disclosure, the devices and/or elements formed over the carrier 202 can be referred to as those formed in the BEOL circuit level.

The dielectric layer 210a is formed to encapsulate the conductive feature 222. The dielectric layer 210a includes materials such as spin-on dielectric (SOD), spin-on glass, spin-on polymers, silicon carbon material, undoped silicate glass, or doped silicon oxide such as phosphor-silicate glass (PSG), borophosphosilicate glass (BPSG), fluorinated silicate glass (FSG), compounds thereof, composites thereof, combinations thereof, and/or other suitable dielectric materials. In some embodiments, the dielectric layer 210a may include silicon oxide (SiO), but the disclosure is not limited thereto.

In some embodiments, the conductive features 222 extend along the Y direction. At least a portion of the conductive features 222 can function as the gate (or gate electrode) of a write transistor. The conductive features 222 may include conductive materials. The conductive materials may include metal, elemental metals, transition metals, or the like. Examples of metal materials may include, for example, but are not limited thereto, Ti, Ta, TiN, Al, W, Cu, metal alloys, other suitable materials, or combinations thereof.

In some embodiments, a conductive material is formed on the carrier 202 by a deposition technique, and then patterned by an etching technique to form the carrier 202 to form the conductive features 222. A dielectric material is formed to cover the carrier 202 and the conductive features 222, and then a planarization technique (e.g., a chemical mechanical planarization (CMP)) is performed to remove excess dielectric material, and thereby produce the conductive feature 222. The deposition technique includes chemical vapor deposition (CVD), physical vapor deposition (PVD), atomic layer deposition (ALD), remote plasma chemical vapor deposition (RPCVD), plasma enhanced chemical vapor deposition (PECVD), high density plasma chemical vapor deposition (HDPCVD), flowable chemical vapor deposition (FCVD), high efficiency aspect ratio deposition (HARP), low pressure chemical vapor deposition (LPCVD), metal-organic chemical vapor deposition (MOCVD), plating, other suitable methods, or combinations thereof. The etching technique includes a dry etching process, a wet etching process, other suitable etching process, or combinations thereof.

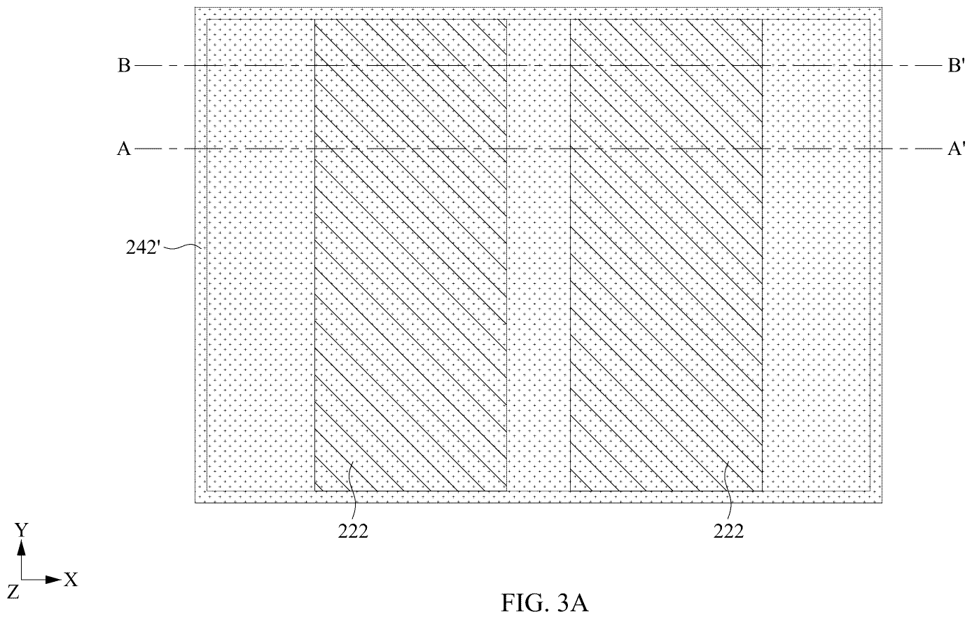

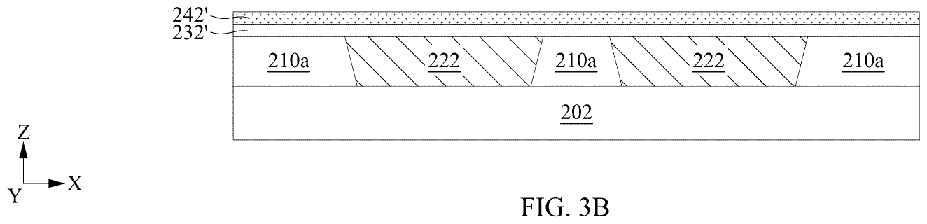

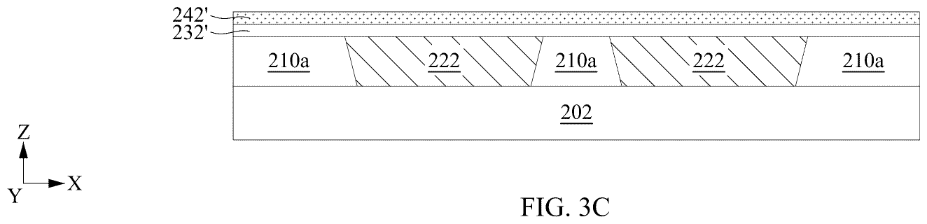

Referring to FIGS. 3A, 3B, and 3C, a gate dielectric material 232′ is formed on the dielectric layer 210a and covers the conductive features 222. A semiconductor material 242′ (or channel material) is formed on the gate dielectric material 232′ and covers the conductive features 222. The gate dielectric material 232′ is configured to form or define a gate dielectric, and the semiconductor material 242′ is configured to form or define a channel layer of a write transistor in subsequent stages.

In some embodiments, the gate dielectric material 232′ includes a high-k dielectric material having a high dielectric constant, whose dielectric constant is greater than about 4. The high-k dielectric material may include hafnium dioxide (HfO₂), zirconium dioxide (ZrO₂), aluminum oxide (Al₂O₃), lanthanum oxide (La₂O₃), titanium oxide (TiO₂), yttrium oxide (Y₂O₃), strontium titanate (SrTiO₃), hafnium oxynitride (HfOₓN_{y}), hafnium silicate, zirconium silicate, other suitable metal-oxides, metal silicates, or combinations thereof. The gate dielectric material 232′ can be formed by ALD, CVD, PVD, RPCVD, PECVD, HDPCVD, FCVD, HARP, LPCVD, MOCVD, plating, other suitable methods, or combinations thereof.

The semiconductor material 242′ includes, for example, oxide semiconductors. Examples of metal materials may include, for example, but are not limited thereto, amorphous indium gallium zinc oxide (IGZO), c-axis aligned crystal (CAAC)-IGZO, ZnO, In₂O₃, Ga₂O₃, InGaZnO, Al₂O₅Zn₂, aluminum doped ZnO (AZO), IWO, TiOx, semiconductor materials comprising other III-V materials, or combinations (e.g., alloys or stacked layers) of semiconductor materials. The semiconductor material 242′ can be formed by ALD, CVD, PVD, RPCVD, PECVD, HDPCVD, FCVD, HARP, LPCVD, MOCVD, plating, other suitable methods, or combinations thereof.

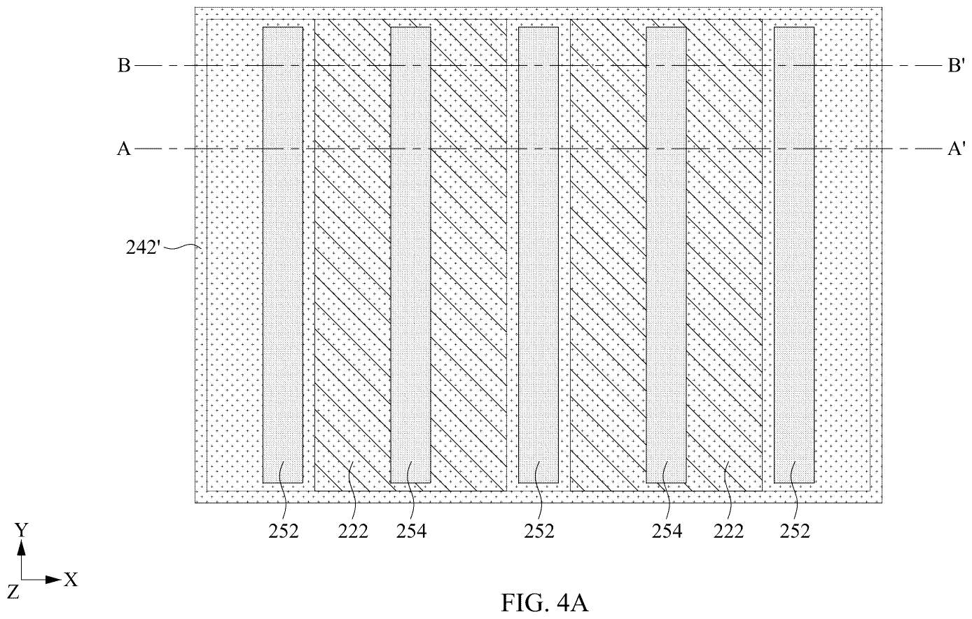

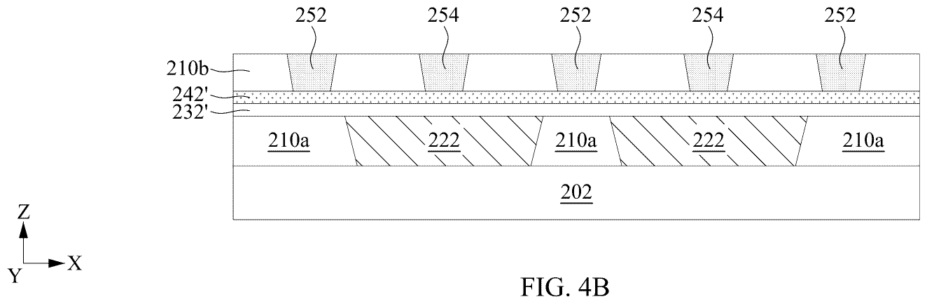

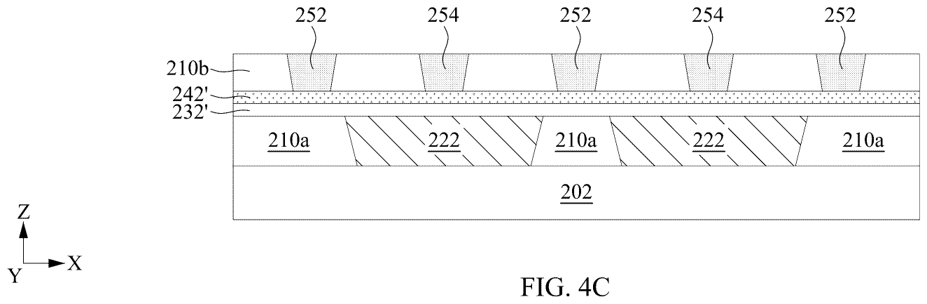

Referring to FIGS. 4A, 4B, and 4C, S/D electrodes 252 and 254 are formed on the semiconductor material 242′. The S/D electrodes 252 and 254 are arranged alternatively along the X direction. In some embodiments, the S/D electrode 252 is disposed at a region corresponding to the peripheral region of the conductive feature 222, and the S/D electrode 254 is disposed at a region corresponding to the central region of the conductive feature 222. The S/D electrodes 252 and 254 include conductive materials, such as metal, elemental metals, transition metals, or the like. In some embodiments, one or more conductive materials are formed on the semiconductor material 242′ by a suitable deposition process, such as CVD, PVD, ALD, HDPCVD, FCVD, HARP, MOCVD, RPCVD, PECVD, LPCVD, or combinations thereof. The conductive material is patterned to form the S/D electrodes 252 and 254 extending along the Y direction. In this disclosure, the “S/D region(s)” or “ S/D electrode(s)” may refer to a source or a drain, individually or collectively dependent upon the context.

A dielectric layer 210b is formed to encapsulate the S/D electrodes 252 and 254. The dielectric layer 210b includes materials such as SOD, spin-on glass, spin-on polymers, silicon carbon material, undoped silicate glass, or doped silicon oxide such as PSG, BPSG, FSG, compounds thereof, composites thereof, combinations thereof, and/or other suitable dielectric materials.

In some embodiments, one or more conductive materials are formed on the semiconductor material 242′, and then patterned to form the S/D electrodes 252 and 254 extending along the Y direction. Next, the dielectric layer 210b is formed to cover the S/D electrodes 252 and 254, and then a planarization technique (e.g., CMP) is performed to planarize the upper surfaces of the dielectric layer 210b, the S/D electrodes 252 and 254.

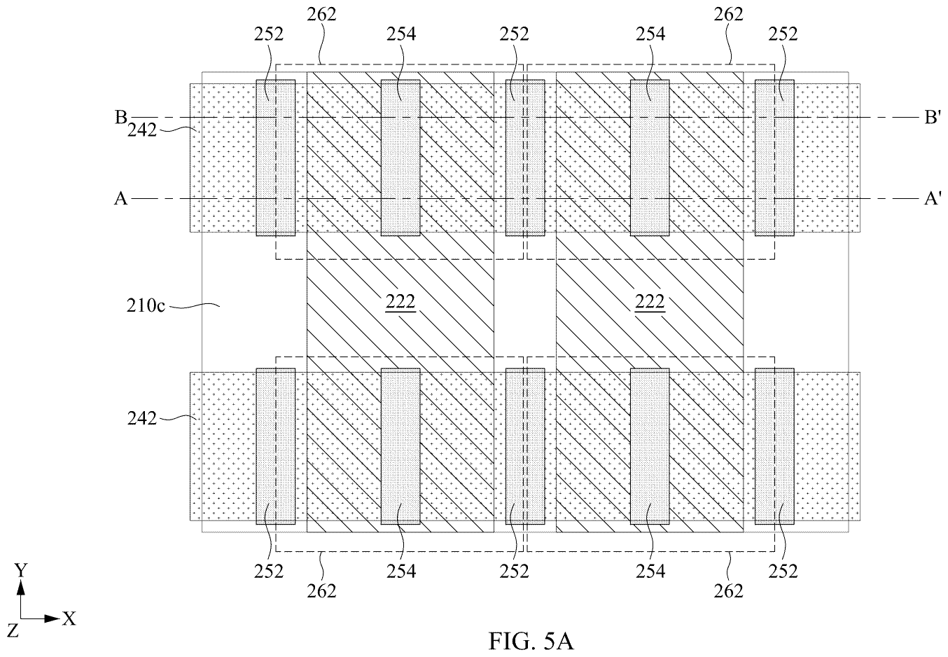

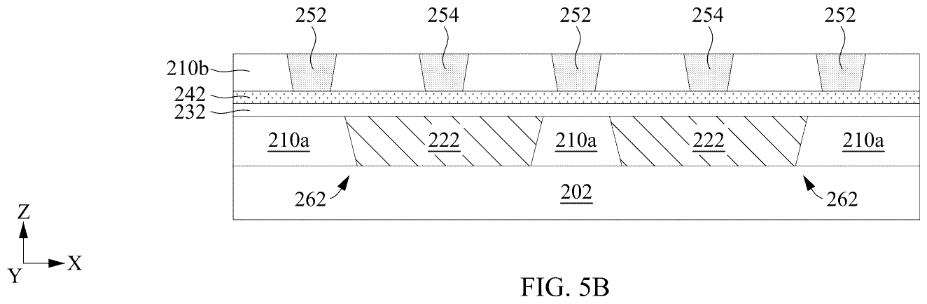

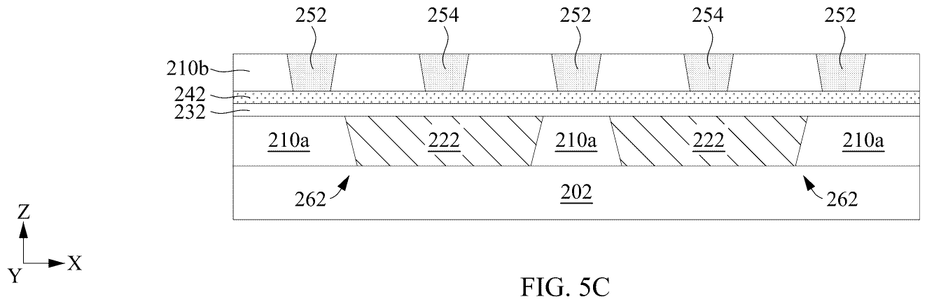

Referring to FIGS. 5A, 5B, and 5C, the S/D electrodes 252 and 254 are patterned to define multiple transistors 262. The semiconductor material 242′ and the gate dielectric material 232′ are patterned to form the semiconductor layer 242 and the gate dielectric 232, respectively. In some embodiments, at least a portion of the semiconductor layer 242 can function as a channel layer (or channel region) of the transistors 262.

The gate dielectric material 232′, semiconductor material 242′, and S/D electrodes 252 and 254 are patterned by one or more etching techniques, such as a dry etching process, a wet etching process, or other suitable etching techniques. A dielectric layer 210c is formed to fill the trenches defined by the S/D electrode 252, S/D electrode 254, gate dielectric 232, and semiconductor layer 242.

In some embodiments, the transistor 262 includes the conductive feature 222, gate dielectric 232, semiconductor layer 242, and S/D electrodes 252 and 254. As shown in FIG. 5A, the semiconductor layer 242 extends along the X direction, and continuously extends across multiple transistors 262. The conductive features 222 extend along the Y direction and continuously extend across multiple transistors 262. In some embodiments, a portion of the conductive features 222 is exposed by the semiconductor layer 242.

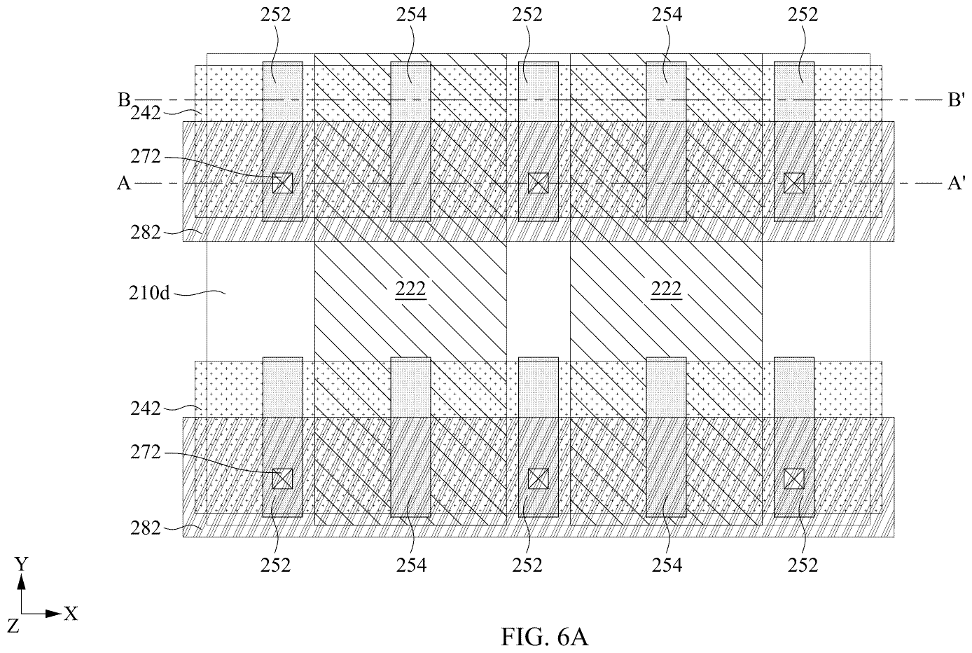

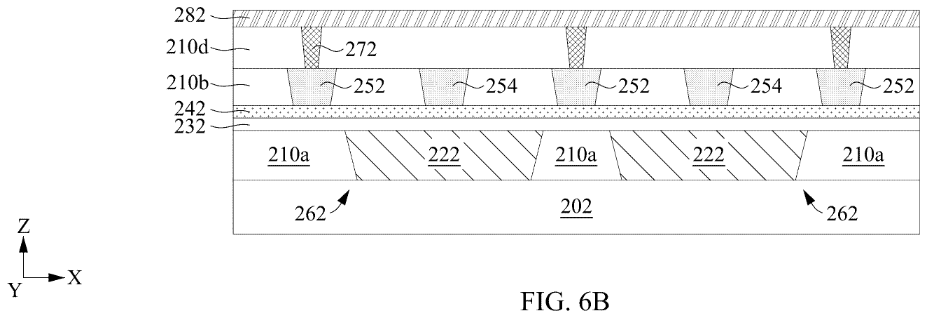

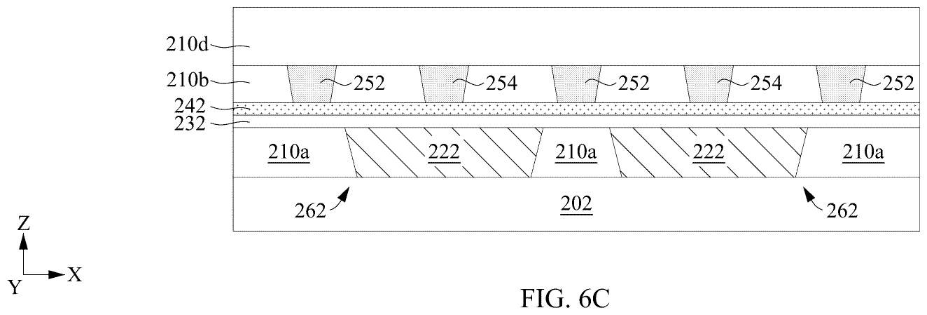

Referring to FIGS. 6A, 6B, and 6C, a dielectric layer 210d is formed on the dielectric layer 210c. In some embodiments, vias 272 are formed on the S/D electrode 252. In some embodiments, conductive lines 282 are formed on the dielectric layer 210d and electrically coupled to the vias 272.

The conductive lines 282 are electrically coupled to the S/D electrode 252 by the vias 272. The conductive lines 282 extend along the X direction. As shown in FIGS. 6A and 6C, a portion of the S/D electrode 252 is exposed by the conductive lines 282, and a portion of the S/D electrode 254 is exposed by the conductive lines 282. In some embodiments, a portion of the semiconductor layer 242 is exposed by the conductive lines 282.

In some embodiments, the dielectric layer 210d is formed on the dielectric layer 210b to cover the S/D electrodes 252 and 254, and a portion of the dielectric layer 210d is patterned to expose the S/D electrode 252. Next, one or more conductive materials are formed on the dielectric layer 210d to fill the openings defined by the dielectric layer 210d. Next, one or more conductive materials are patterned to form the vias 272 and the conductive lines 282. In some embodiments, one or more conductive materials are deposited by a suitable deposition process, such as CVD, PVD, ALD, HDPCVD, FCVD, HARP, MOCVD, RPCVD, PECVD, LPCVD, or combinations thereof.

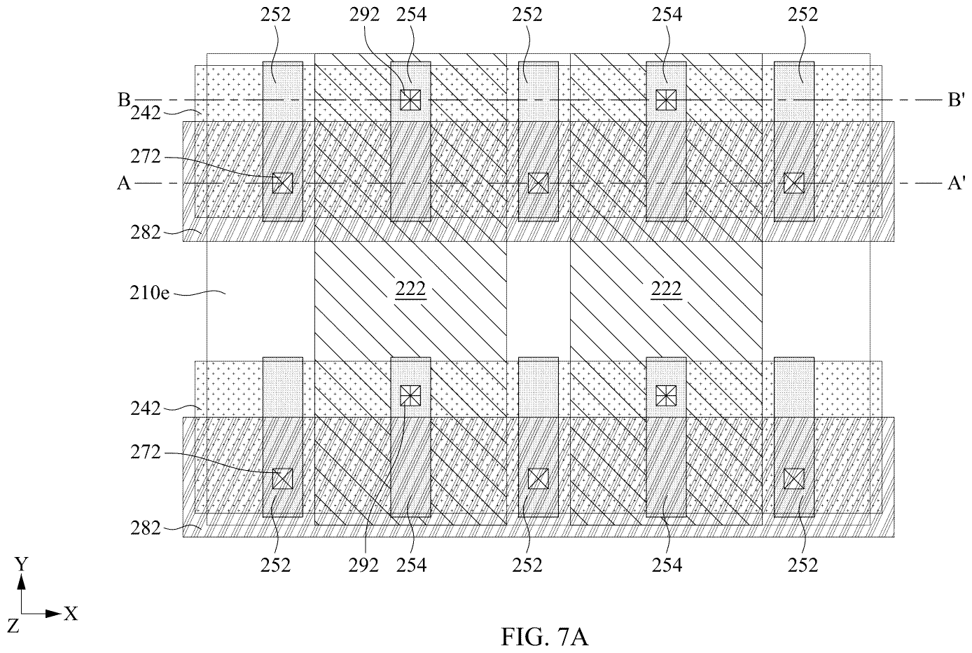

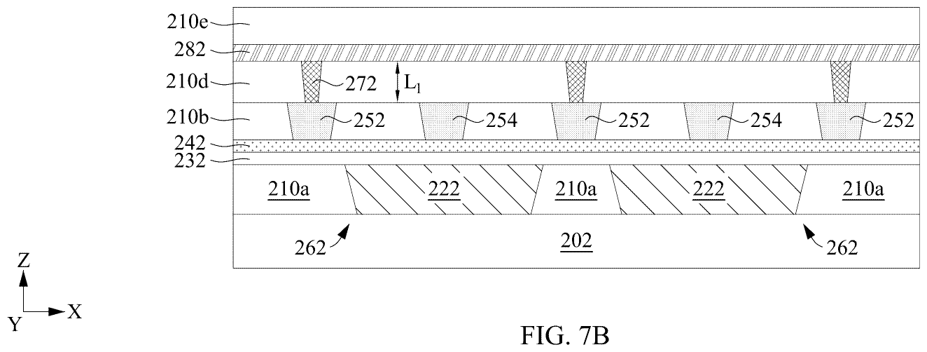

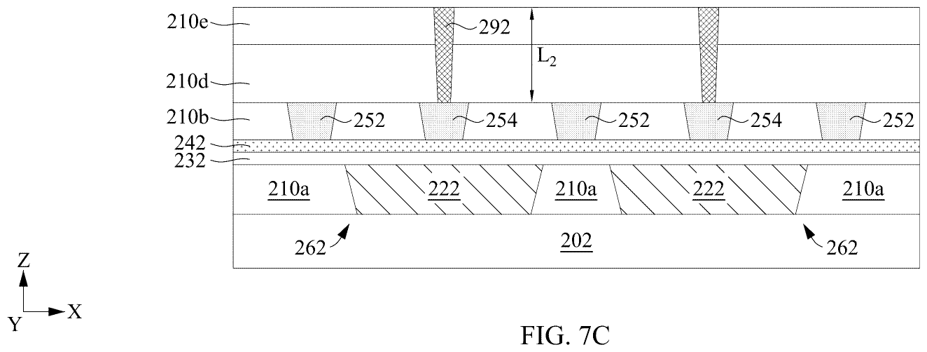

Referring to FIGS. 7A, 7B, and 7C, a dielectric layer 210e is formed on the dielectric layer 210d and on the conductive lines 282. In some embodiments, vias 292 are formed on the S/D electrode 254.

The dielectric layer 210e is disposed on the dielectric layer 210d and covers the conductive lines 282. The dielectric layer 210e encapsulates the vias 292.

The vias 292 are configured to be electrically coupled to the gate of a read transistor. As shown in FIG. 7A, the vias 272 and vias 292 are misaligned along the X direction. As shown in FIGS. 7B and 7C, each of the vias 272 has a length (or thickness) L₁, and each of the vias 292 has a length (or thickness) L₂ along the Z direction. In some embodiments, the length L₂ is greater than the length L₁.

In some embodiments, a portion of the dielectric layer 210e is patterned to expose the S/D electrode 254, and one or more conductive materials are formed to fill the openings defined by the dielectric layer 210e, thereby producing the vias 292.

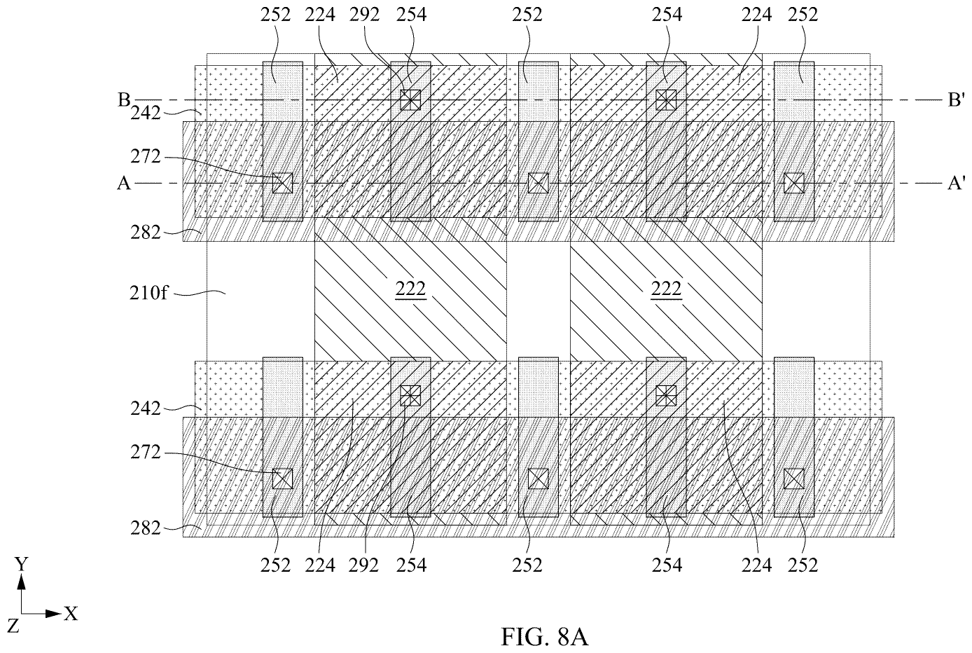

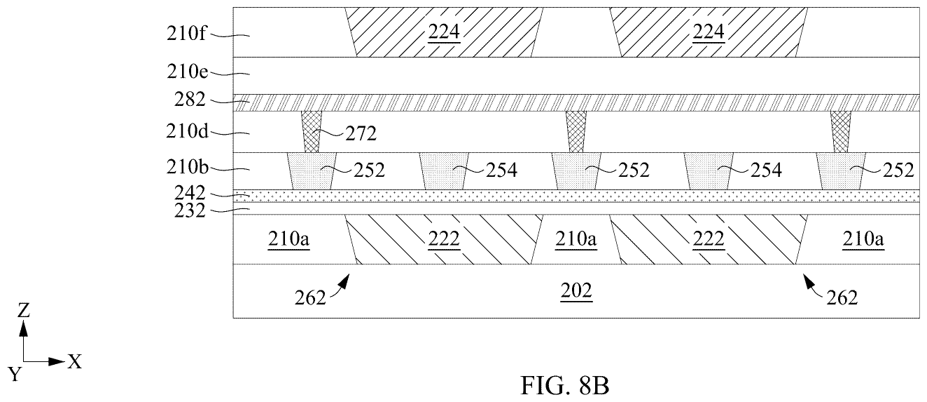

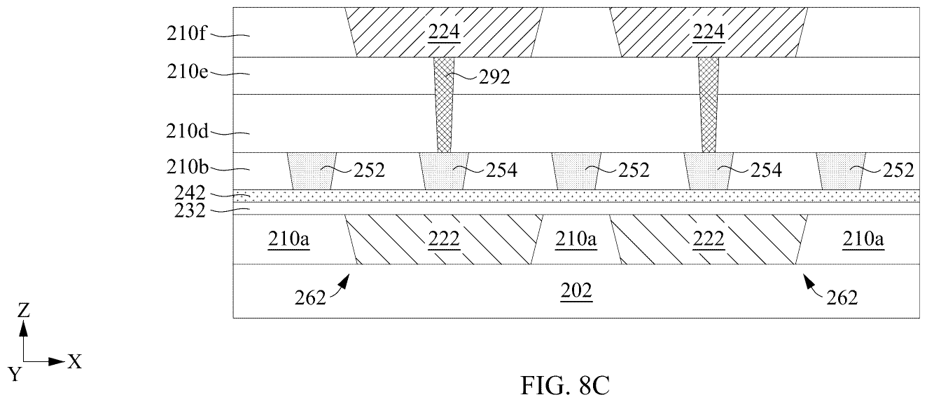

Referring to FIGS. 8A, 8B, and 8C, a dielectric layer 210f is formed on the dielectric layer 210e and on the vias 292. In some embodiments, the conductive features 224 are formed on the vias 292.

The conductive features 224 are electrically coupled to the S/D electrodes 254 by the vias 292. The conductive features 224 can function as the gate (or gate electrode) of a read transistor. As shown in FIG. 8A, the conductive features 224 are disconnected along the Y direction. In some embodiments, a portion of the conductive features 222 is exposed by the conductive features 224. The conductive features 224 may include conductive material, such as metal, elemental metals, transition metals, or the like. Examples of metal materials may include, for example, but are not limited thereto, Ti, Ta, TiN, Al, W, Cu, metal alloys, other suitable materials, or combinations thereof. The conductive feature 224 can be formed by a suitable deposition process, such as CVD, PVD, ALD, HDPCVD, FCVD, HARP, MOCVD, RPCVD, PECVD, LPCVD, or combinations thereof.

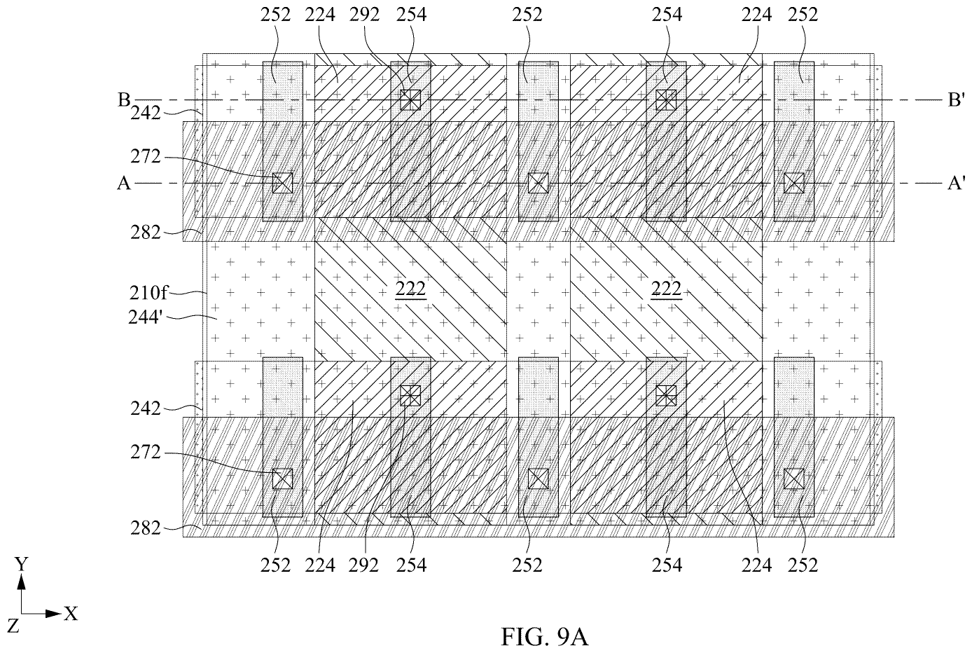

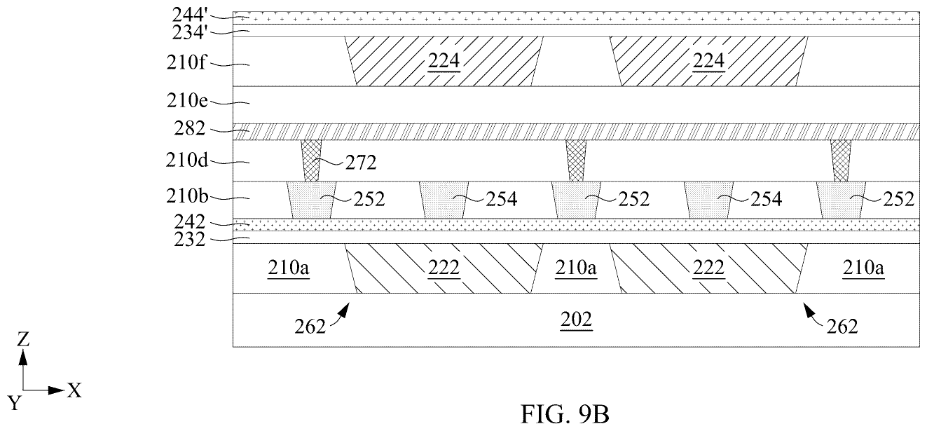

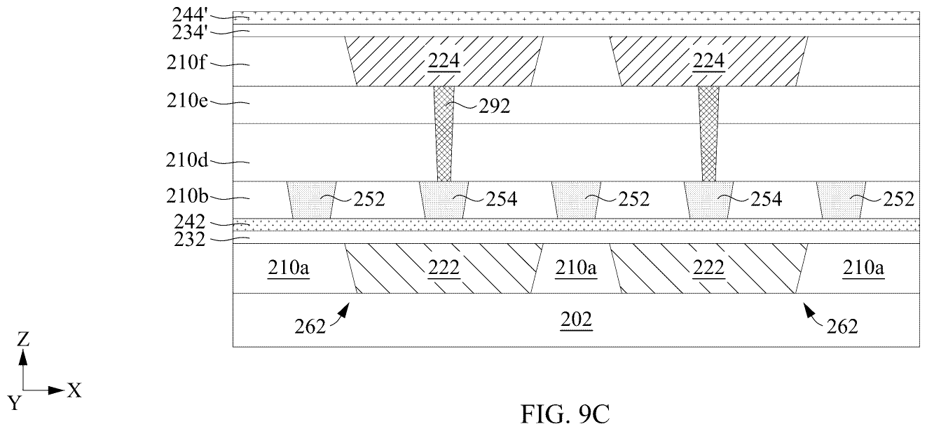

Referring to FIGS. 9A, 9B, and 9C, a gate dielectric material 234′ is formed on the dielectric layer 210f and covers the conductive features 224. A semiconductor material 244′ (or channel material) is formed on the gate dielectric material 234′ and covers the conductive features 224. The gate dielectric material 234′ is configured to form or define a gate dielectric, and the semiconductor material 244′ is configured to form or define a channel layer of a read transistor in subsequent stages.

In some embodiments, the gate dielectric material 234′ includes a high-k dielectric material having a high dielectric constant, such as HfO₂, ZrO₂, Al₂O₃, La₂O₃, TiO₂, Y₂O₃, SrTiO₃, HfOₓN_{y}, hafnium silicate, zirconium silicate, other suitable metal-oxides, metal silicates, or combinations thereof. The gate dielectric material 232′ can be formed by ALD, CVD, PVD, RPCVD, PECVD, HDPCVD, FCVD, HARP, LPCVD, MOCVD, plating, other suitable methods, or combinations thereof.

The semiconductor material 244′ includes, for example, oxide semiconductors. Examples of metal materials may include, for example, but are not limited thereto, amorphous IGZO, CAAC-IGZO, ZnO, In₂O₃, Ga₂O₃, InGaZnO, Al₂O₅Zn₂, AZO, IWO, TiOx, semiconductor materials comprising other III-V materials, or combinations (e.g., alloys or stacked layers) of semiconductor materials. The semiconductor material 242′ can be formed by ALD, CVD, PVD, RPCVD, PECVD, HDPCVD, FCVD, HARP, LPCVD, MOCVD, plating, other suitable methods, or combinations thereof.

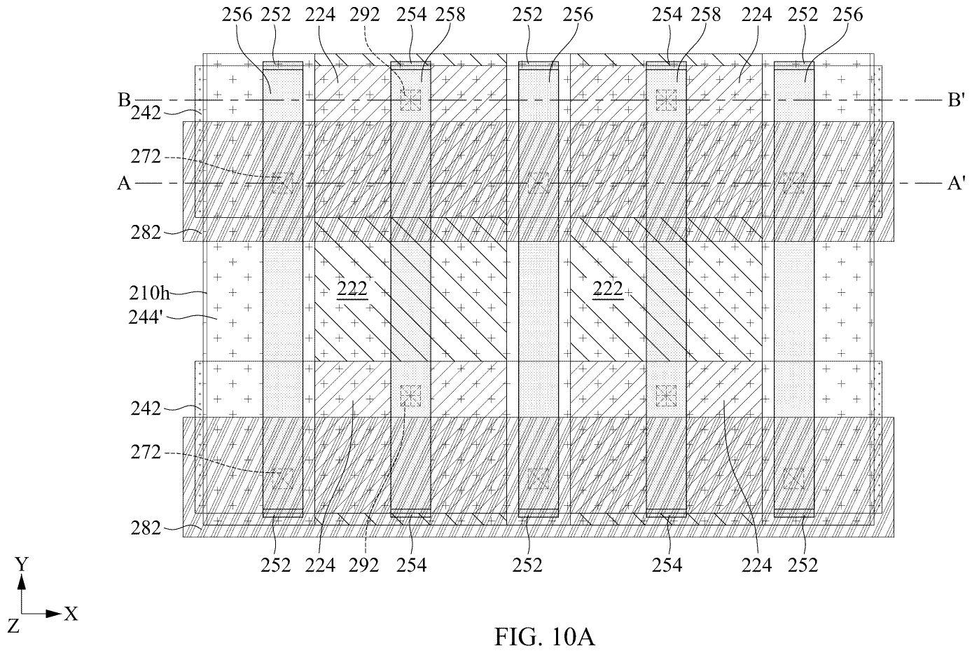

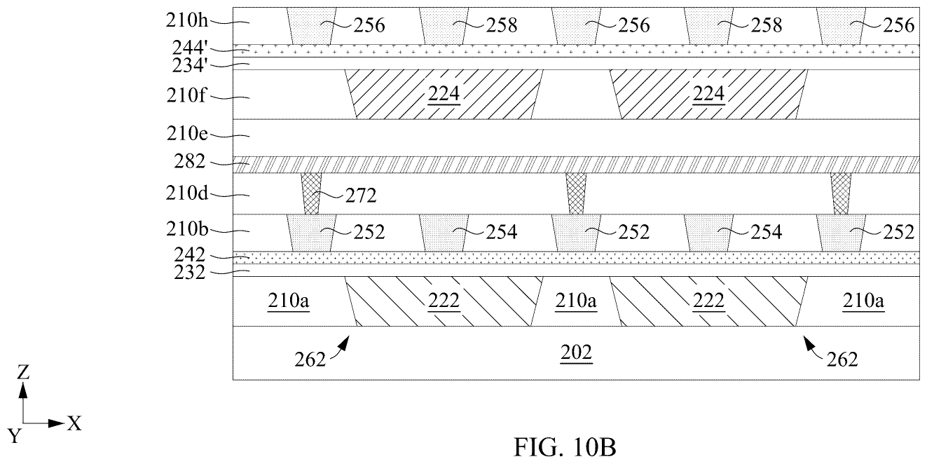

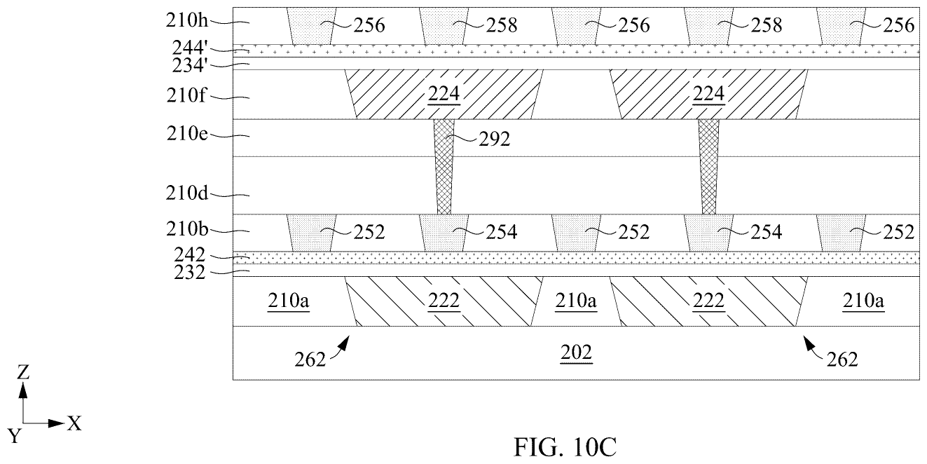

Referring to FIGS. 10A, 10B, and 10C, S/D electrodes 256 and 258 are formed on the semiconductor material 244′. The S/D electrodes 256 and 258 extend along the Y direction. The S/D electrodes 256 and 258 are arranged alternatively along the X direction. In some embodiments, the S/D electrode 256 is disposed at a region corresponding to the peripheral region of the conductive feature 224, and the S/D electrode 258 is disposed at a region corresponding to the central region of the conductive feature 224. The S/D electrodes 256 and 258 include conductive materials, such as metal, elemental metals, transition metals, or the like. In some embodiments, one or more conductive materials are formed on the semiconductor material 244′ by a suitable deposition process, such as CVD, PVD, ALD, HDPCVD, FCVD, HARP, MOCVD, RPCVD, PECVD, LPCVD, or combinations thereof. The conductive material is patterned to form the S/D electrodes 256 and 258 extending along the Y direction.

A dielectric layer 210h encapsulates the S/D electrodes 256 and 258. In some embodiments, the dielectric material is formed to cover the S/D electrodes 256 and 258, and then a planarization technique (e.g., CMP) is performed to planarize the upper surfaces of the dielectric layer 210h, and the S/D electrodes 256 and 258.

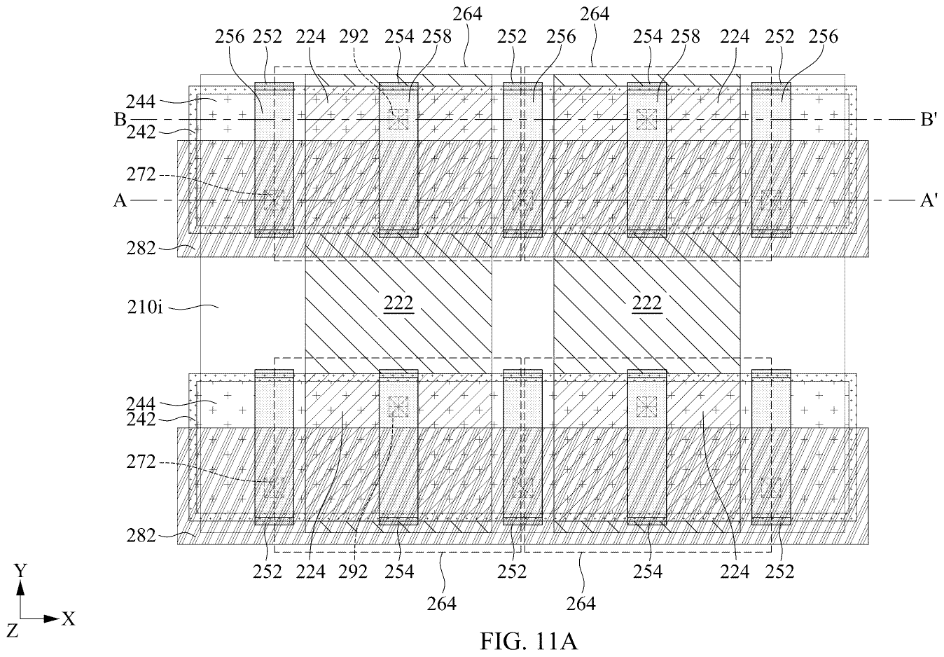

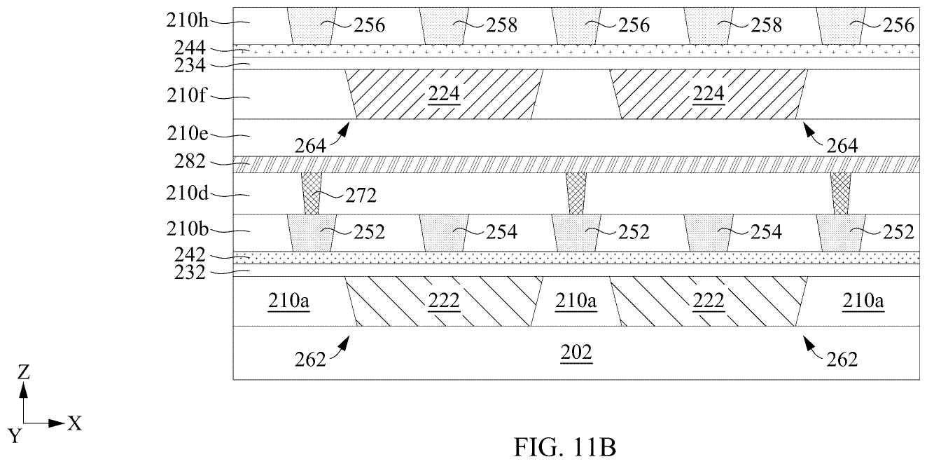

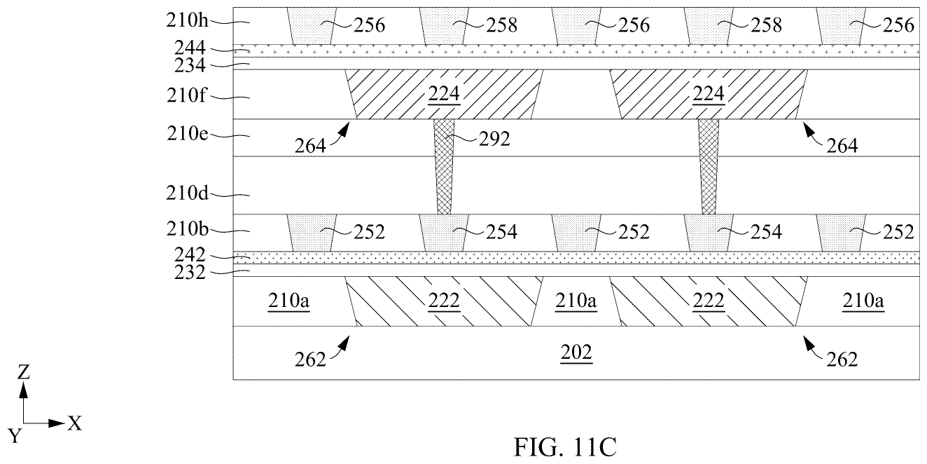

Referring to FIGS. 11A, 11B, and 11C, the S/D electrodes 256 and 258 are patterned to define multiple transistors 264. The semiconductor material 244′ and the gate dielectric material 234′ are patterned to form the semiconductor layer 244 and the gate dielectric 234, respectively. At least a portion of the semiconductor layer 244 can function as a channel layer (or channel region) of the transistors 264.

The gate dielectric material 234′, semiconductor material 244′, and S/D electrodes 256 and 258 are patterned by one or more etching techniques, such as a dry etching process, a wet etching process, or other suitable etching techniques. A dielectric layer 210i is formed to fill the trenches defined by the S/D electrode 256, S/D electrode 258, gate dielectric 234, and semiconductor layer 244.

Each of the transistors 264 includes the conductive feature 224, gate dielectric 234, semiconductor layer 244, S/D electrode 256, and S/D electrode 258. As shown in FIG. 11A, the semiconductor layer 244 extends along the X direction and continuously extends across multiple transistors 264. In some embodiments, the S/D electrode 252 overlaps the S/D electrode 256 along the Z direction. In some embodiments, the S/D electrode 254 overlaps the S/D electrode 258 along the Z direction.

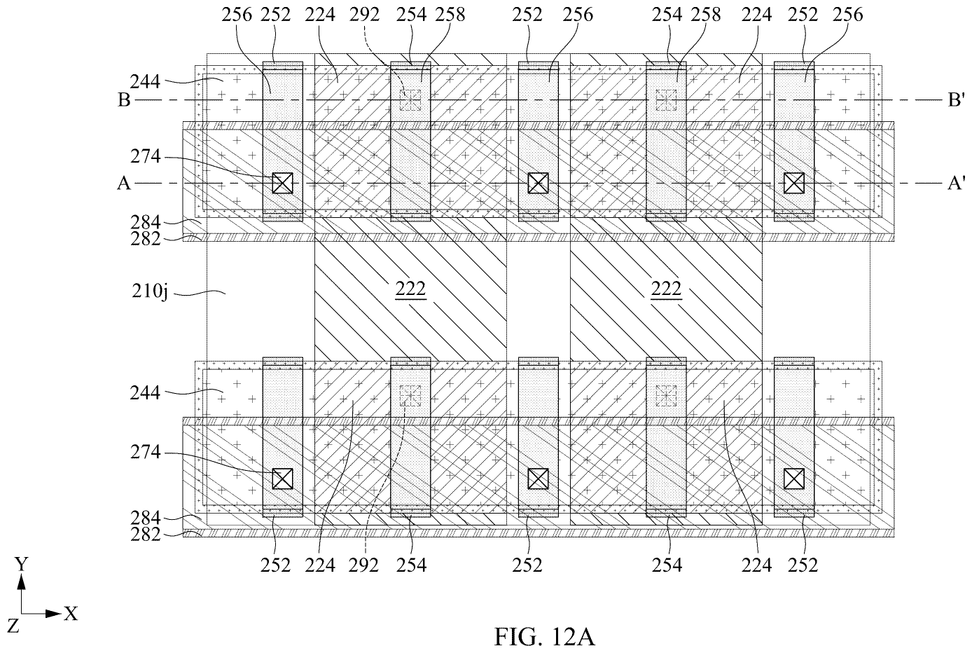

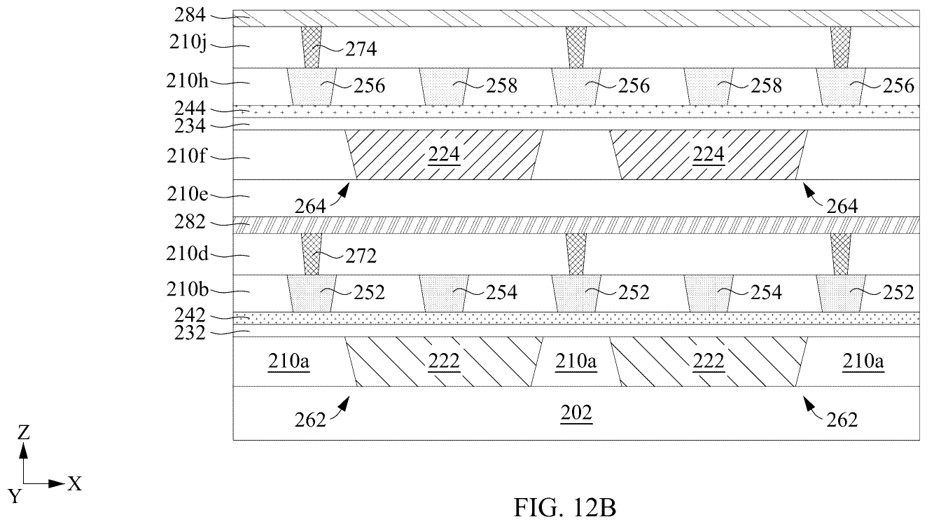

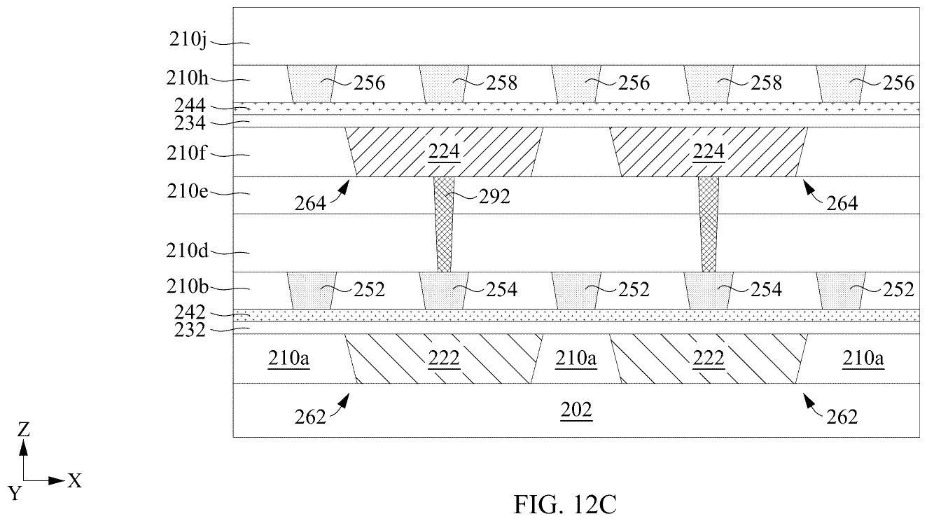

Referring to FIGS. 12A, 12B, and 12C, a dielectric layer 210j is formed on the dielectric layer 210h. In some embodiments, vias 274 are formed on the S/D electrodes 256. In some embodiments, conductive lines 284 are formed on the dielectric layer 210j and electrically coupled to the vias 274.

The conductive lines 284 are electrically coupled to the S/D electrode 256 by the vias 274. The conductive lines 284 extend along the X direction. As shown in FIGS. 12A and 12C, a portion of the S/D electrodes 256 is exposed by the conductive lines 284, and a portion of the S/D electrodes 256 is exposed by the conductive lines 284. In some embodiments, a portion of the semiconductor layer 244 is exposed by the conductive lines 284.

In some embodiments, the dielectric layer 210j is formed to cover the S/D electrodes 256 and 258, and a portion of the dielectric layer 210j is patterned to expose the S/D electrode 256. Next, one or more conductive materials are formed on the dielectric layer 210j to fill the openings defined by the dielectric layer 210j. Next, one or more conductive materials are patterned to form the vias 274 and the conductive lines 284. In some embodiments, one or more conductive materials are deposited by a suitable deposition process, such as CVD, PVD, ALD, HDPCVD, FCVD, HARP, MOCVD, RPCVD, PECVD, LPCVD, or combinations thereof.

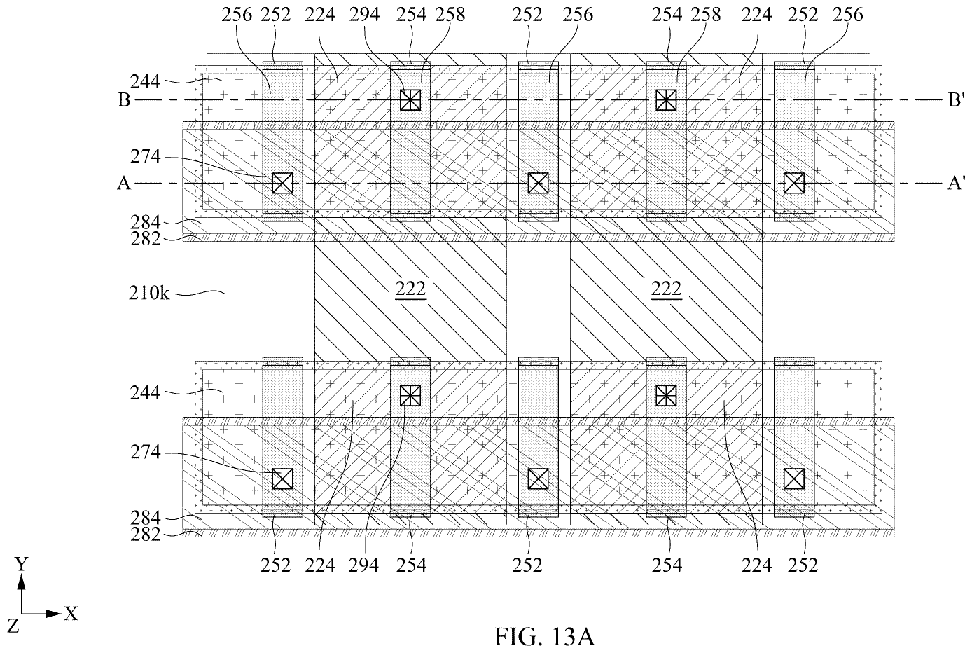

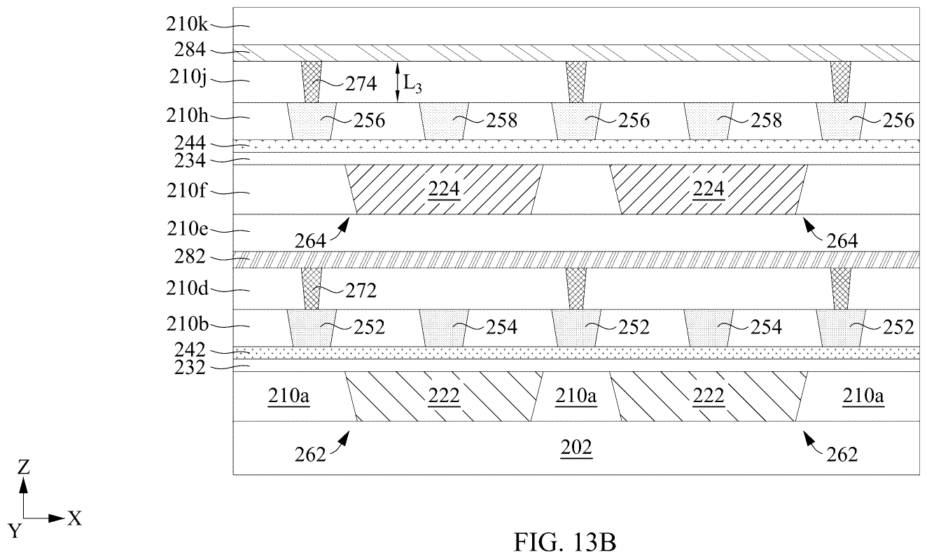

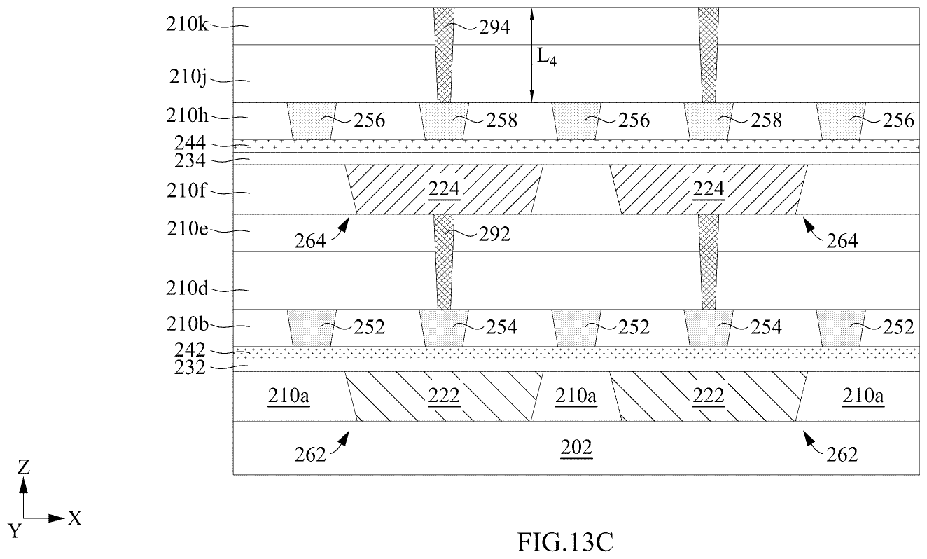

Referring to FIGS. 13A, 13B, and 13C, a dielectric layer 210k is formed on the dielectric layer 210j and on the conductive line 284. In some embodiments, vias 294 are formed on the S/D electrode 258.

The vias 294 are configured to be electrically coupled to the read word line of a memory device. As shown in FIG. 13A, the vias 274 and 294 are misaligned along the X direction. As shown in FIGS. 12B and 12C, each of the vias 274 has a length (or thickness) L₃, and each of the vias 294 has a length (or thickness) L₄ along the Z direction. In some embodiments, the length L₄ is greater than the length L₃.

The dielectric layer 210k encapsulates the vias 294. In some embodiments, a portion of the dielectric layer 210k is patterned to expose the S/D electrode 258, and one or more conductive materials are formed to fill the openings defined by the dielectric layer 210k, thereby producing the vias 294.

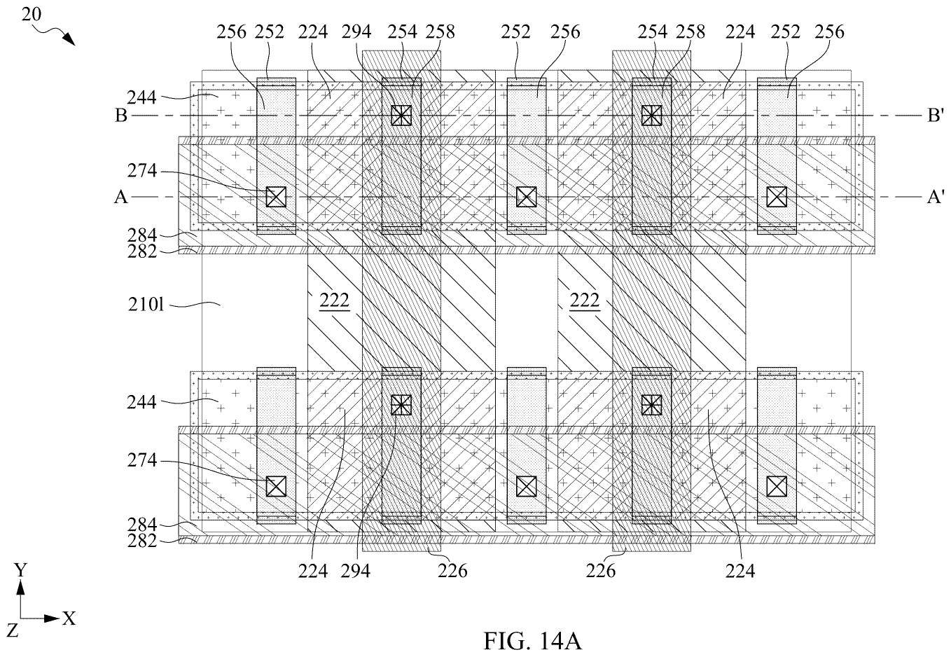

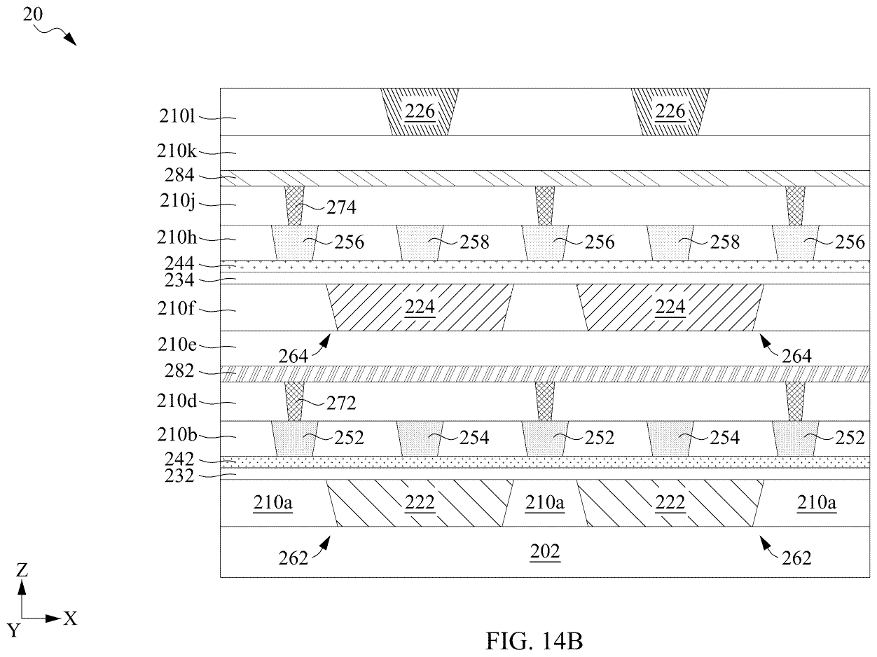

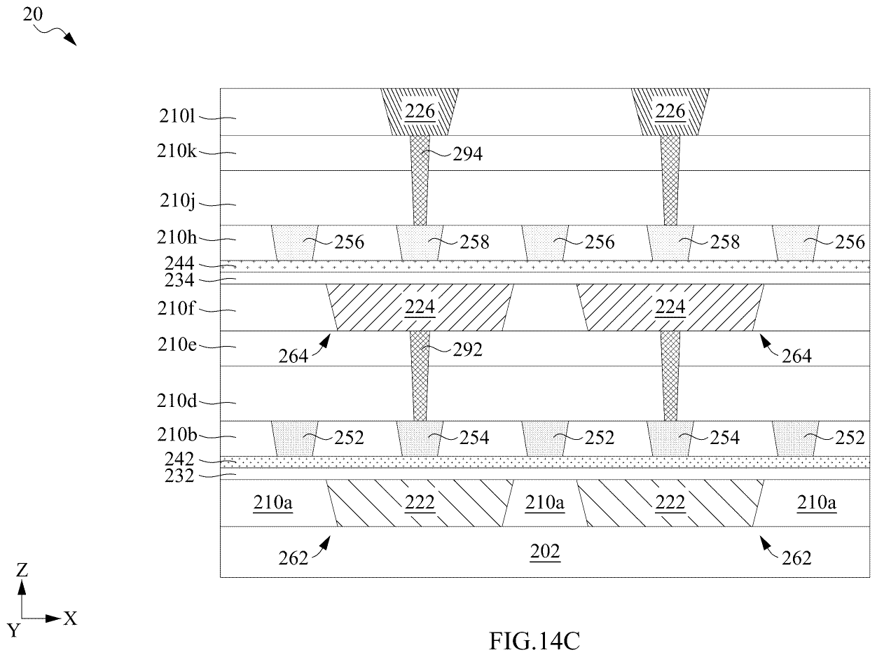

Referring to FIGS. 14A, 14B, and 14C, a dielectric layer 210l is formed on the dielectric layer 210k and on the vias 294. In some embodiments, conductive features 226 are formed on the vias 294. A semiconductor device 20 is produced.

The conductive features 226 are electrically coupled to the S/D electrodes 258 by the vias 294. As shown in FIG. 14A, the conductive features 226 extend along the Y direction and continuously extend across multiple transistors 264. The conductive features 226 may include conductive material, such as metal, elemental metals, transition metals, or the like. Examples of metal materials may include, for example, but are not limited thereto, Ti, Ta, TiN, Al, W, Cu, metal alloys, other suitable materials, or combinations thereof. The conductive feature 226 can be formed by a suitable deposition process, such as CVD, PVD, ALD, HDPCVD, FCVD, HARP, MOCVD, RPCVD, PECVD, LPCVD, or combinations thereof.

In some embodiments, the transistor 262 can function as a write transistor (e.g., transistor T1 as shown in FIG. 1). In some embodiments, the conductive feature 222 can function as the gate (e.g., terminal t11 as shown in FIG. 1) and the write word line (e.g., write word line WWL as shown in FIG. 1). In some embodiments, the S/D electrode 252 can function as the drain terminal (e.g., transistor t12 as shown in FIG. 1) of the transistor 262. In some embodiments, the S/D electrode 254 can function as the source terminal (e.g., transistor t13 as shown in FIG. 1) of the transistor 262. In some embodiments, the conductive line 282 can function as a write bit line (e.g., write bit line WBL as shown in FIG. 1).

In some embodiments, the transistor 264 can function as a read transistor (e.g., transistor T2 as shown in FIG. 1). In some embodiments, the conductive feature 224 can function as the gate (e.g., terminal t21 as shown in FIG. 1) of the transistor 264. In some embodiments, the S/D electrode 256 can function as the source terminal (e.g., transistor t23 as shown in FIG. 1) of the transistor 264. In some embodiments, the S/D electrode 258 can function as the drain terminal (e.g., terminal t22 as shown in FIG. 1) of the transistor 264. In some embodiments, the conductive line 284 can function as a read bit line (e.g., read bit line RBL as shown in FIG. 1). In some embodiments, the conductive feature 226 can function as a read word line (e.g., read bit line RWL as shown in FIG. 1).

In this embodiment, the transistors 264 are stacked over the transistors 262 along the Z direction. Further, the transistors 264 have a structure the same as or similar to that of the transistors 262. Accordingly, the transistors 264 can have a dimension (e.g., volume or surface area) substantially the same as that of the transistors 262, which improves the stacking density of the semiconductor device 20. Further, a portion of the stages for forming the transistors 262 and 264 can be integrated with those for forming the elements on the logic region, which reduces the cost and process complexity.

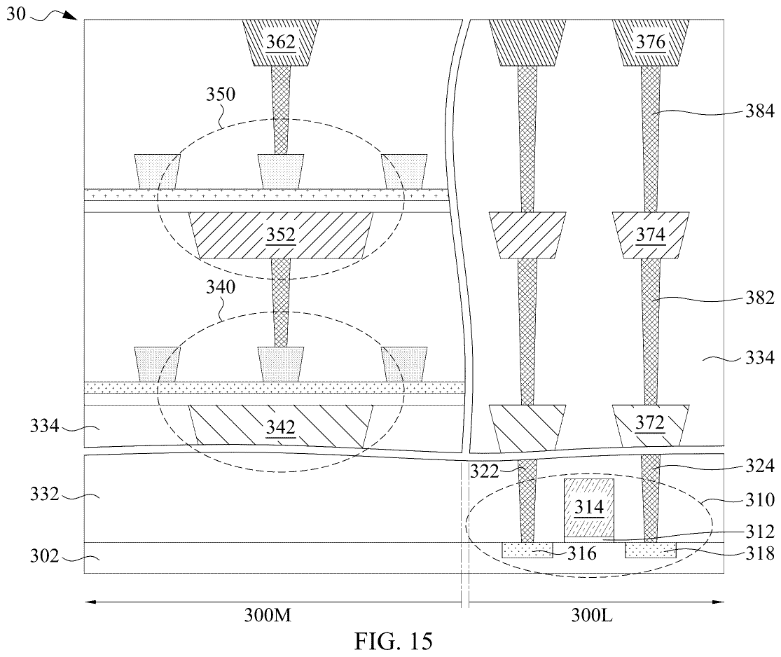

FIG. 15 is a cross-sectional view illustrating a semiconductor device 30 according to aspects of the present disclosure in one or more embodiments.

In some embodiments, the semiconductor device 30 may include a plurality of functional regions. For example, the semiconductor device 30 includes a memory region 300M and a logic region 300L that are defined by isolation structures (not shown). The memory region 300M may include a plurality of memory devices as shown in FIG. 14A to FIG. 14C. The logic region 300L may include circuitry for processing information received from the memory devices and for controlling reading and writing functions of the memory devices.

The semiconductor device 30 includes a substrate 302. The substrate 302 may be a semiconductor substrate, such as a bulk semiconductor, a semiconductor-on-insulator (SOI) substrate, or the like, which may be doped (e.g., with a p type or an n type dopant) or undoped. The substrate can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. In some embodiments, the substrate 302 may have a multilayer structure, or the substrate 302 may include a multilayer compound semiconductor structure.

The semiconductor device 30 includes a transistor 310. The transistor 310 includes a gate dielectric 312 and a gate electrode 314. The gate dielectric 312 includes one or more suitable dielectric materials such as silicon oxide (SiO₂), silicon nitride (Si₃N₄), silicon oxynitride (SiON), low-k dielectrics such as carbon doped oxides, extremely low-k dielectrics such as porous carbon doped silicon dioxide, a polymer such as polyimide, the like, or a combination thereof. In other embodiments, the gate dielectric 312 includes dielectric materials having a high-k material, such as HfO₂, HfZrOₓ, HfSiOₓ, HfTiOₓ, HfAlOₓ, TiN, the like, or a combination thereof.

The gate electrode 314 is disposed on the gate dielectric 312. The gate electrode 314 includes polysilicon and/or metallic material including elements and compounds such as Ti, Ta, TiN, Al, W, Cu, Mo, TiN, TaN, NiSi, or other suitable conductive materials.

In some embodiments, the S/D regions 316 and 318 include doped regions within the substrate 302. The S/D regions 316 and 318 include p-type or n-type dopants therein. In some embodiments, n-type includes As, P, other group V elements, or any combination thereof. In some embodiments, p-type includes dopants such as B, other group III elements, or any combination thereof.

In some embodiments, a portion of the substrate 302 may function as a channel layer extending between the S/D regions 316 and 318. In the illustrated exemplary embodiments, a planar transistor (e.g., transistor 310) is used as an example to explain the concept of the present disclosure. Fin field-effect transistors (FinFETs), gate-all-around (GAA) transistors, or complementary field-effect transistors (CFETs) may also adopt the embodiments of the present disclosure.

The semiconductor device 30 includes contacts 322 and 324 and a dielectric structure 332. The contacts 322 and 324 penetrate the dielectric structure 332. The contacts 322 and 324 are connected to the S/D regions 316 and 318, respectively.

The dielectric structure 332 covers the transistor 310. The dielectric structure 332 includes materials such as SOD, spin-on glass, spin-on polymers, silicon carbon material, undoped silicate glass, or doped silicon oxide such as PSG, BPSG, FSG, compounds thereof, composites thereof, combinations thereof, and/or other suitable dielectric materials. The dielectric structure 332 may also be referred to as an interlayer dielectric (ILD).

In some embodiments, the transistor 310, the contact 322, and the contact 324 are formed in the FEOL circuit level of the semiconductor device 30.

The semiconductor device 30 includes a dielectric structure 334. The dielectric structure 334 is disposed on the dielectric structure 332. In some embodiments, the material of the dielectric structure 334 is the same as or similar to that of the dielectric structure 332. In some embodiments, the dielectric structure 334 includes multiple dielectric layers, such as the dielectric layers 210a to 210l as shown in FIGS. 14B and 14C. In this disclosure, the devices and/or elements formed within the dielectric structure 334 indicate that those devices and/or elements are formed in the BEOL circuit level of the semiconductor device 30.

In some embodiments, the memory region 300M includes memory devices that can be fabricated by the stages as shown in FIGS. 2A to 14A, FIGS. 2B to 14B, and FIGS. 2C to 14C. For example, the semiconductor device 30 includes a transistor 340 and a transistor 350. The transistors 340 and 350 are disposed on the memory region 300M. In some embodiments, the transistor 340 corresponds to the transistor 262, and the transistor 350 corresponds to the transistor 264 of the semiconductor device 20.

The memory region 300M includes conductive features 342, 352, and 362 located at different levels (or elevation) with respect to the upper surface of the substrate 302. In some embodiments, the conductive feature 342 corresponds to the conductive feature 222, the conductive feature 352 corresponds to the conductive feature 224, and the conductive feature 362 corresponds to the conductive feature 226 of the semiconductor device 20.

In some embodiments, the conductive features 342, 352, and 362 are located at the levels corresponding to the conductive traces, such as the metal zero (M0) layer, metal one (M1) layer, metal two (M2) layer, metal three (M3) layer, metal four (M4) layer, and the like, of the logic region 300L. For example, the logic region 300L includes conductive layers 372, 374, and 376. Vias 382 extend between the conductive layers 372 and 374. Vias 384 extend between the conductive layers 374 and 376. The conductive layers 372, 374, and 376 as well as the vias 382 and 384 are formed within the dielectric structure 334. In some embodiments, the conductive features 342, 352, and 362 are located at levels substantially the same as those of the conductive layers 372, 374, and 376, respectively.

In this embodiment, the processes for manufacturing the devices and/or elements on the logic region 300L and the memory region 300M can be integrated, which reduces the cost and process complexity.

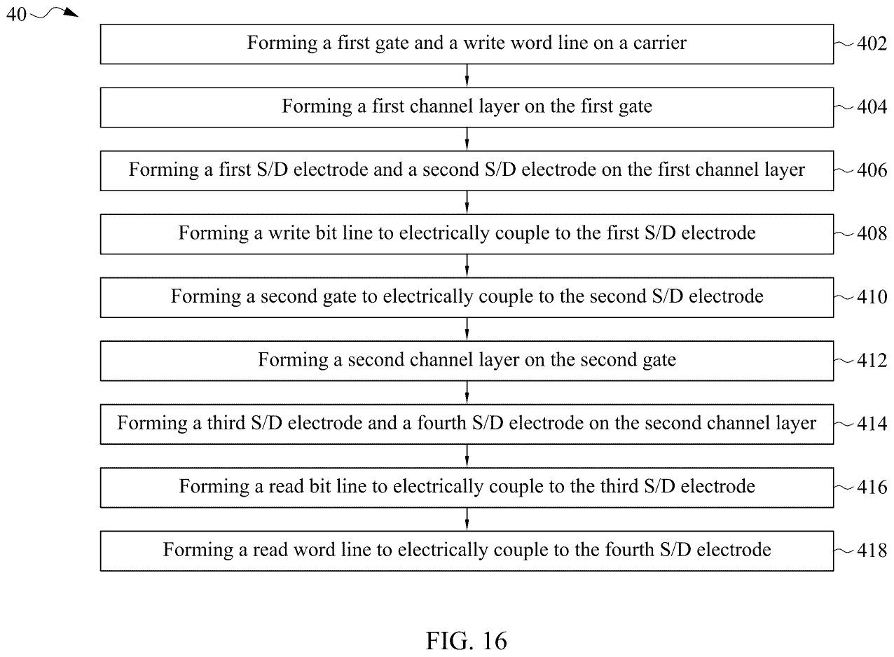

FIG. 16 is a flowchart of a method 40 for manufacturing a semiconductor device according to various aspects of the present disclosure.

The method 40 begins with an operation 402 in which a first gate and a write word line are formed on a carrier. FIGS. 2A to 2C illustrate the stage corresponding to the operation 402.

The method 40 continues with the operation 404 in which a first channel layer is formed on the first gate. FIGS. 3A to 3C illustrate the stage corresponding to the operation 404.

The method 40 continues with the operation 406 in which a first S/D electrode and a second S/D electrode are formed on the first channel layer. FIGS. 4A to 4C and FIGS. 5A to 5C illustrate the stage corresponding to the operation 406.

The method 40 continues with the operation 408 in which a write bit line is formed to electrically couple to the first S/D electrode. FIGS. 6A to 6C illustrate the stage corresponding to the operation 408.

The method 40 continues with the operation 410 in which a second gate is formed to electrically couple to the second S/D electrode. FIGS. 7A to 7C and FIGS. 8A to 8C illustrate the stage corresponding to the operation 410.

The method 40 continues with the operation 412 in which a second channel layer is formed on the second gate. FIGS. 9A to 9C illustrate the stage corresponding to the operation 412.

The method 40 continues with the operation 414 in which a third S/D electrode and a fourth S/D electrode are formed on the second channel layer. FIGS. 10A to 10C and FIGS. 11A to 11C illustrate the stage corresponding to the operation 414.

The method 40 continues with the operation 416 in which a read bit line is formed to electrically couple to the third S/D electrode. FIGS. 12A to 12C illustrate the stage corresponding to the operation 416.

The method 40 continues with the operation 418 in which a read word line is formed to electrically couple to the fourth S/D electrode. FIGS. 13A to 13C and FIGS. 14A to 14C illustrate the stage corresponding to the operation 418.

The method 40 is merely an example, and is not intended to limit the present disclosure beyond what is explicitly recited in the claims. Additional operations can be provided before, during, and after the method 40, and some operations described can be replaced, eliminated, or reordered for additional embodiments of the method.

According to an embodiment, a semiconductor device includes a substrate, a first transistor, and a second transistor. The first transistor includes a first gate electrode on the substrate and a first channel layer on the first gate electrode and extending along a first direction. The second transistor is stacked over the first transistor along a second direction substantially orthogonal to the first direction. The second transistor includes a second gate electrode and a second channel layer on the second gate electrode.

According to an embodiment, a method for forming a semiconductor device is provided. The method includes providing a substrate, forming a first transistor on the substrate, and forming a second transistor over the first transistor. Forming the first transistor includes forming a first gate electrode and forming a first channel layer on the first gate electrode. The first channel layer extends along a first direction. The second transistor is over the first transistor along a second direction substantially orthogonal to the first direction. Forming the second transistor includes forming a second gate electrode and forming a second channel layer on the second gate electrode.

According to an embodiment, a method for forming a semiconductor device is provided. The method includes providing a substrate, forming a first transistor on the substrate, and forming a second transistor over the first transistor. Forming the first transistor includes forming a first gate electrode, forming a first channel layer on the first gate electrode, and forming a first source/drain (S/D) electrode and a second S/D electrode on the first channel layer. The method also includes forming a first via on the first S/D electrode. Forming the second transistor includes forming a second gate electrode on the first via. The second gate electrode is electrically coupled to the first S/D electrode through the first via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first transistor on the substrate, comprising:
a first gate electrode; and
a first channel layer on the first gate electrode and extending along a first direction;
a second transistor stacked over the first transistor along a second direction substantially orthogonal to the first direction, comprising:
a second gate electrode; and
a second channel layer on the second gate electrode.

2. The semiconductor device according to claim 1, wherein the first transistor comprises a first source/drain (S/D) electrode stacked over the first channel layer.

3. The semiconductor device according to claim 2, wherein the first S/D electrode is electrically coupled to the second gate electrode.

4. The semiconductor device according to claim 2, further comprising:
a write word line electrically coupled to the first gate electrode; and
a write bit line,
wherein the first transistor comprises a second S/D electrode stacked over the first channel layer and electrically coupled to the write bit line.

5. The semiconductor device according to claim 4, wherein the write bit line is disposed between the second S/D electrode and the second gate electrode along the second direction.

6. The semiconductor device according to claim 4, further comprising:
a first via electrically connecting the first S/D electrode and the second gate electrode; and
a second via electrically connecting the second S/D electrode and the write bit line,
wherein a length of the first via is different from a length of the second via along the second direction.

7. The semiconductor device according to claim 1, wherein the second channel layer extends along the first direction.

8. The semiconductor device according to claim 1, wherein the first gate electrode extends along a third direction substantially orthogonal to the first direction and the second direction.

9. The semiconductor device according to claim 2, wherein the second transistor comprises a third S/D electrode, and the second channel layer is disposed between the second gate electrode and the third S/D electrode along the second direction.

10. The semiconductor device according to claim 9, further comprising:
a read bit line electrically coupled to the third S/D electrode by a third via; and
a read word line electrically coupled to a fourth S/D electrode of the second transistor by a fourth via,
wherein a length of the third via is different from a length of the fourth via along the second direction.

11. A method of manufacturing a semiconductor device, comprising:
providing a substrate;
forming a first transistor on the substrate, comprising:
forming a first gate electrode; and
forming a first channel layer on the first gate electrode, wherein the first channel layer extends along a first direction; and
forming a second transistor over the first transistor along a second direction substantially orthogonal to the first direction, comprising:
forming a second gate electrode; and
forming a second channel layer on the second gate electrode.

12. The method according to claim 11, further comprising:
forming a first source/drain (S/D) electrode on the first channel layer;
forming a second S/D electrode on the first channel layer; and
forming a first via on the first S/D electrode,
wherein the second gate electrode is electrically coupled to the first S/D electrode through the first via.

13. The method according to claim 12, further comprising:
forming a second via on the second S/D electrode; and
forming a write bit line on the second via,
wherein a length of the first via is different from a length of the second via along the second direction.

14. The method according to claim 12, wherein forming the first channel layer comprises:
forming a first channel material on the first gate electrode;
forming a first conductive layer on the first channel material; and
patterning the first conductive layer and the first channel material to form the first channel layer, the first S/D electrode, and the second S/D electrode.

15. The method according to claim 14, wherein forming the second channel layer comprises:
forming a second channel material on the second gate electrode;
forming a second conductive layer on the first channel material; and
patterning the second conductive layer and the second channel material to form the second channel layer as well as a third S/D electrode and a fourth S/D electrode of the second transistor.

16. The method according to claim 11, wherein forming the second transistor comprises:
forming a gate dielectric on the second gate electrode,
wherein the second channel layer is formed on the gate dielectric.

17. A method of manufacturing a semiconductor device, comprising:
providing a substrate;
forming a first transistor on the substrate, comprising:
forming a first gate electrode;
forming a first channel layer on the first gate electrode; and
forming a first source/drain (S/D) electrode and a second S/D electrode on the first channel layer; and
forming a first via on the first S/D electrode; and
forming a second transistor on the first transistor, comprising:
forming a second gate electrode on the first via, wherein the second gate electrode is electrically coupled to the first S/D electrode through the first via.

18. The method according to claim 17, wherein forming the second transistor comprises:
forming a second channel layer on the second gate electrode, wherein the first channel layer extends along a first direction, and the second channel layer extends along the first direction.

19. The method according to claim 18, wherein forming the second transistor comprises:
forming a third S/D electrode and a fourth S/D electrode on the second channel layer,
wherein the second channel layer is between the third S/D electrode and the second gate electrode along a second direction substantially orthogonal to the first direction.

20. The method according to claim 18, further comprising:
forming a second via on the second S/D electrode; and
forming a write bit line on the second via,
wherein a length of the first via is greater than a length of the second via along a second direction substantially orthogonal to the first direction.
